(19) United States
(12) Patent Application Publication
(10) Pub. No.: US 2025/0220983 A1
(43) Pub. Date: Jul. 3, 2025

(54) SEMICONDUCTOR STRUCTURE AND METHOD FOR MANUFACTURING THE SAME

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 18/623,373

(22) Filed: Apr. 1, 2024

(30) Foreign Application Priority Data
Dec. 29, 2023 (CN) 202311846790.0

(51) Int. Cl. H01L 29/06; H01L 21/225; H01L 29/20; H01L 29/207; H01L 29/66; H01L 29/778

(52) U.S. Cl. CPC H10D 62/10; H10D 30/015; H10D 30/475; H01L 21/2258; H10D 62/8503; H10D 62/854

(57) ABSTRACT

A method for manufacturing a semiconductor structure includes: sequentially stacking a substrate, a heterojunction structure layer, and a P-type semiconductor layer; remaining the P-type semiconductor layer in a gate region and etching the P-type semiconductor layer in a non-gate region; growing a sacrificial layer on the P-type semiconductor layer, and magnesium ions on a surface of the P-type semiconductor layer diffusing into the sacrificial layer; etching the sacrificial layer; and repeating N times processes of growing the sacrificial layer first and then etching the sacrificial layer until a concentration of the magnesium ions on the surface of the P-type semiconductor layer is less than a preset value, so that the magnesium ions on the surface is reduced to form a high-resistance region on the surface of the P-type semiconductor layer, obtaining an enhancement mode HEMT device with low gate leakage current, high breakdown voltage, and stable threshold voltage.

### CROSS-REFERENCE TO RELATED APPLICATIONS

The present application claims priority to the Chinese Patent Application 202311846790.0, filed on Dec. 29, 2023, the entire content of which is incorporated herein by reference.

### TECHNICAL FIELD

The present disclosure relates to the field of semiconductor technologies, and in particular, to a semiconductor structure and a method for manufacturing the same.

### BACKGROUND

A GaN high electron mobility transistor (HEMT) has advantages of wide band gap, high breakdown field strength, high electron mobility, high energy conversion efficiency, and the like, and has great potential in power electronics applications with high-frequency and high-power.

At present, main methods for preparing an enhancement mode HEMT device are adopting P-GaN gate, but it is difficult to make a high-quality P-type GaN material.

### SUMMARY

In view of this, embodiments of the present disclosure provide a semiconductor structure and a method for manufacturing the same, so as to further improve a quality of P-type GaN in an enhancement mode HEMT device prepared by using a P-GaN gate.

According to a first aspect, an embodiment of the present disclosure provides a method for manufacturing a semiconductor structure, which includes: sequentially stacking a substrate, a heterojunction structure layer, and a P-type semiconductor layer; remaining the P-type semiconductor layer in a gate region and etching the P-type semiconductor layer in a non-gate region; growing a sacrificial layer on the P-type semiconductor layer, and magnesium ions on a surface of the P-type semiconductor layer diffusing into the sacrificial layer; etching the sacrificial layer; and repeating N times processes of growing the sacrificial layer on the P-type semiconductor layer first and then etching the sacrificial layer until a concentration of the magnesium ions on the surface of the P-type semiconductor layer is less than a preset value to form a high-resistance region.

As an alternative embodiment, the method for manufacturing the semiconductor structure further includes: providing a source electrode on the heterojunction structure layer in a source region, providing a drain electrode on the heterojunction structure layer in a drain region, and providing a gate electrode in the gate region.

As an alternative embodiment, the etching the sacrificial layer includes: etching the sacrificial layer by in-situ etching.

As an alternative embodiment, after the high-resistance region is formed, the method for manufacturing the semiconductor structure further includes: growing the sacrificial layer on the P-type semiconductor layer, and a material of the sacrificial layer is AlN.

As an alternative embodiment, the sacrificial layer is a non-intentionally doped layer.

As an alternative embodiment, after the remaining the P-type semiconductor layer in a gate region and etching the P-type semiconductor layer in a non-gate region, and before the growing the sacrificial layer on the P-type semiconductor layer, the method for manufacturing the semiconductor structure further includes: conformally providing a protection layer on the P-type semiconductor layer.

As an alternative embodiment, a material of the sacrificial layer is different from a material of the protection layer.

As an alternative embodiment, an etching selectivity ratio of the sacrificial layer to the protection layer is greater than 1, the material of the sacrificial layer includes any one of: GaN and AlGaN, and the material of the protection layer includes any one of: AlN and AlGaN.

As an alternative embodiment, an etching selectivity ratio of the sacrificial layer to the protection layer is less than 1, the material of the sacrificial layer is AlN, and the material of the protection layer is AlGaN.

As an alternative embodiment, the material of the protection layer is different from a material of the P-type semiconductor layer.

As an alternative embodiment, the etching the P-type semiconductor layer in a non-gate region includes: etching the P-type semiconductor layer in the non-gate region with an etching depth less than a thickness of the P-type semiconductor layer, the P-type semiconductor layer in the gate region is a first P-type region, and a portion of the P-type semiconductor layer in the non-gate region remained after the P-type semiconductor layer in the non-gate region is etched is a second P-type region.

As an alternative embodiment, along a direction from the substrate to the P-type semiconductor layer, a thickness of the second P-type region ranges from 1 nm to 50 nm.

As an alternative embodiment, along a direction from the substrate to the P-type semiconductor layer, a thickness of the high-resistance region includes at least one of: a thickness of the high-resistance region located in the non-gate region being equal to a thickness of the second P-type region, or a thickness of the high-resistance region located in the gate region being greater than or equal to a thickness of the second P-type region and less than a thickness of the first P-type region.

As an alternative embodiment, a concentration of magnesium ions inside the P-type semiconductor layer is greater than 1E17/cm³.

As an alternative embodiment, a concentration of magnesium ions located in the high-resistance region is less than 1E15/cm³.

As an alternative embodiment, the P-type semiconductor layer includes a low-resistance region and the high-resistance region that are stacked along a direction from the substrate to the P-type semiconductor layer, and a concentration of magnesium ions located in the low-resistance region gradually decreases along the direction from the substrate to the P-type semiconductor layer.

As an alternative embodiment, the method for manufacturing the semiconductor structure further includes: annealing the P-type semiconductor layer to activate magnesium ions of the P-type semiconductor layer.

According to another aspect, an embodiment of the present disclosure provides a semiconductor structure, which includes: a substrate, a heterojunction structure layer, and a P-type semiconductor layer sequentially stacked, the P-type semiconductor layer being at least located in a gate region, and a concentration of magnesium ions on a surface of the P-type semiconductor layer being less than a preset value to form a high-resistance region.

As an alternative embodiment, the P-type semiconductor layer includes a first P-type region located in the gate region and a second P-type region located in a non-gate region, and a thickness of the first P-type region is greater than a thickness of the second P-type region along a direction from the substrate to the P-type semiconductor layer.

As an alternative embodiment, the P-type semiconductor layer includes a low-resistance region and the high-resistance region that are stacked along a direction from the substrate to the P-type semiconductor layer, and a concentration of magnesium ions located in the low-resistance region gradually decreases along the direction from the substrate to the P-type semiconductor layer.

### BRIEF DESCRIPTION OF THE DRAWINGS

FIG. 1 is a flowchart of a method for manufacturing a semiconductor structure according to an embodiment of the present disclosure.

FIG. 2 to FIG. 7 are schematic diagrams of intermediate structures corresponding to a semiconductor structure in a manufacturing process according to an embodiment of the present disclosure.

FIG. 8 to FIG. 10 are schematic diagrams of intermediate structures corresponding to a semiconductor structure in a manufacturing process according to another embodiment of the present disclosure.

FIG. 11 to FIG. 13 are schematic diagrams of intermediate structures corresponding to a semiconductor structure in a manufacturing process according to another embodiment of the present disclosure.

### DETAILED DESCRIPTIONS OF THE EMBODIMENTS

Technical solutions in the embodiments of the present disclosure may be clearly and completely described below with reference to the accompanying drawings in the embodiments of the present disclosure. Apparently, the described embodiments are a part of the embodiments of the present disclosure, rather than all the embodiments. All other embodiments obtained by a person of ordinary skill in the art based on the embodiments of the present disclosure without creative efforts shall fall within the protection scope of the present disclosure.

Conventional AlGaN/GaN high electron mobility transistors are normally-on devices, however, in an actual application scenario, an enhancement mode HEMT device is often required considering an actual cost, a fault protection, and the like. After decades of development, a method for preparing the enhancement mode HEMT device mainly include adopting a trench gate, implanting fluorine ions, adopting a P-GaN gate, and the like, and the enhancement mode HEMT device prepared by adopting the P-GaN gate has been commercialized and has shown a broad development prospect.

However, it is relatively difficult to prepare a high-quality P-type GaN material, for example, in a process of activating Mg ions in the P-type GaN material by high-temperature annealing, a surface of P-type GaN is damaged, so that a large number of defects are introduced due to a deterioration of a surface morphology, causing an electric leakage and pre-breakdown of a device, and further generating a problem of reliability degradation.

In order to further improve a quality of P-type GaN in an enhancement mode HEMT device prepared by adopting a P-GaN gate, the present disclosure provides a semiconductor structure and a method for manufacturing the same, and the method includes: sequentially stacking a substrate, a heterojunction structure layer, and a P-type semiconductor layer; remaining the P-type semiconductor layer in a gate region and etching the P-type semiconductor layer in a non-gate region; growing a sacrificial layer on the P-type semiconductor layer, and magnesium ions on a surface of the P-type semiconductor layer diffusing into the sacrificial layer; etching the sacrificial layer; and repeating N times processes of growing the sacrificial layer on the P-type semiconductor layer first and then etching the sacrificial layer until a concentration of the magnesium ions on the surface of the P-type semiconductor layer is less than a preset value to form a high-resistance region. In the present disclosure, a method for repeating multiple times processes of growing the sacrificial layer first and then etching the sacrificial layer is adopted, so that the magnesium ions on the surface of the P-type semiconductor layer can be reduced to form the high-resistance region on the surface of the P-type semiconductor layer, obtaining an enhancement mode HEMT device with low gate leakage current, high breakdown voltage, and stable threshold voltage.

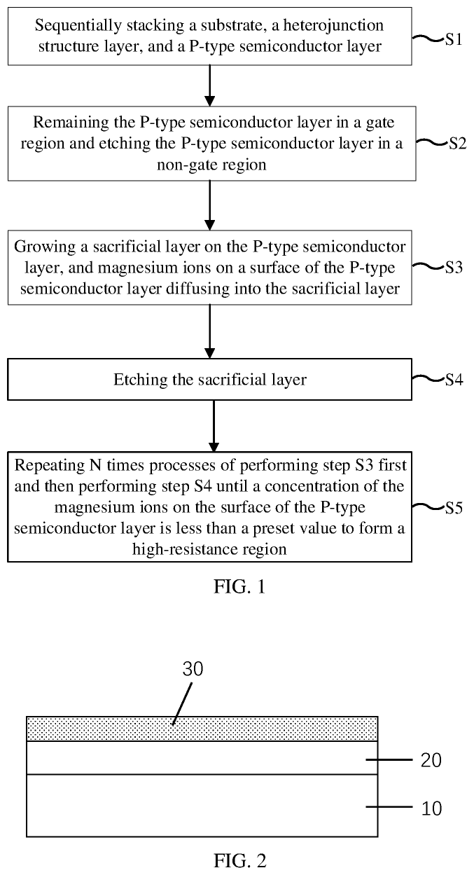

The semiconductor structure and the method for manufacturing the same mentioned in the present disclosure are further illustrated below in conjunction with FIGS. 1 to 13.

FIG. 1 is a flowchart of a method for manufacturing a semiconductor structure according to an embodiment of the present disclosure; and FIG. 2 to FIG. 7 are schematic diagrams of intermediate structures corresponding to a semiconductor structure in a manufacturing process according to an embodiment of the present disclosure. As shown in FIG. 1, the method for manufacturing a semiconductor structure according to an embodiment of the present disclosure includes following steps.

Step S1: sequentially stacking a substrate, a heterojunction structure layer, and a P-type semiconductor layer.

As shown in FIG. 2, the substrate 10, the heterojunction structure layer 20, and the P-type semiconductor layer 30 are sequentially stacked. A material of the substrate 10 include any one or a combination of more of Si, Al₂O₃, GaN, SiC, or AlN. The heterojunction structure layer 20 includes a channel layer and a barrier layer stacked along a direction away from the substrate 10, and a band gap of a material of the barrier layer is greater than that of the channel layer. A material of the channel layer and a material of the barrier layer may include a Group III nitride material, and a two-dimensional electron gas may be formed at an interface between the channel layer and the barrier layer. In an optional solution, the channel layer is a GaN layer and the barrier layer is an AlGaN layer. In other alternative solutions, a combination of materials of the channel layer and the barrier layer may also be GaN/AlN, GaN/InN, GaN/InAlGaN, GaAs/AlGaAs, GaN/InAlN, or InN/InAlN. A material of the P-type semiconductor layer 30 includes a Group III nitride material, and a concentration of magnesium ions of the P-type semiconductor layer 30 is greater than 1E17/cm³.

Step S2: remaining the P-type semiconductor layer in a gate region and etching the P-type semiconductor layer in a non-gate region.

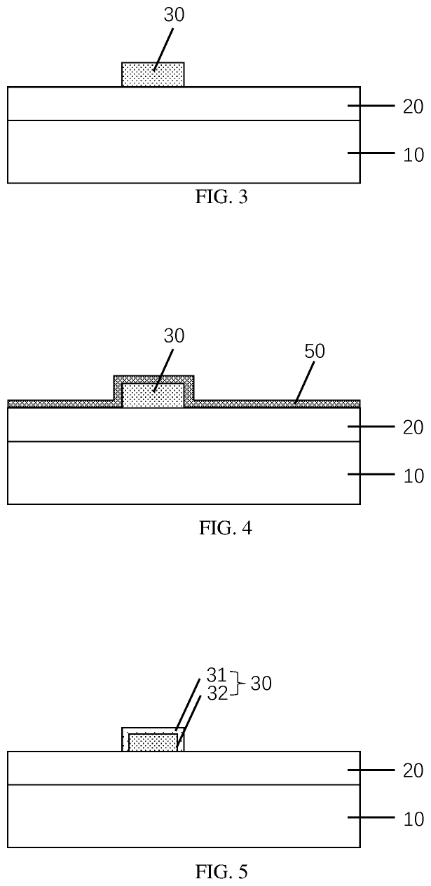

As shown in FIG. 3, the P-type semiconductor layer 30 in the gate region is remained, and the P-type semiconductor layer 30 in the non-gate region is etched.

Step S3: growing a sacrificial layer on the P-type semiconductor layer, and magnesium ions on a surface of the P-type semiconductor layer diffusing into the sacrificial layer.

As shown in FIG. 4, the sacrificial layer 50 is grown on the P-type semiconductor layer 30, and the magnesium ions on the surface of the P-type semiconductor layer 30 diffuse into the sacrificial layer 50. The sacrificial layer 50 is a non-intentionally doped layer, the magnesium ions on the surface of the P-type semiconductor layer 30 diffuse into the sacrificial layer 50, and impurity ions in an epitaxial cavity may also diffuse into the sacrificial layer 50, reducing a concentration of the magnesium ions on the surface of the P-type semiconductor layer 30 and a concentration of the impurity ions in the epitaxial cavity. Optionally, the sacrificial layer 50 is carbon-doped, iron-doped, or iron-carbon co-doped. Further, the carbon-doping, the iron-doping, or the iron-carbon co-doping of the sacrificial layer 50 is graded doping. The sacrificial layer 50 is doped with iron or carbon to form a deep level trap, providing a recombination center to trap holes on the surface of the P-type semiconductor layer 30, and further reducing the concentration of the magnesium ions on the surface of the P-type semiconductor layer 30 while reducing the concentration of the impurity ions in the epitaxial cavity.

Step S4: etching the sacrificial layer.

The sacrificial layer 50 is etched to form an intermediate structure shown in FIG. 3. The sacrificial layer 50 is etched by using an in-situ etching method, and using the in-situ etching method does not introduce impurities, reducing an interface state density, and further facilitating decrease of a current collapse effect of a device subsequently prepared and decrease of a leakage current.

Step S5: repeating N times processes of performing step S3 first and then performing step S4 until a concentration of the magnesium ions on the surface of the P-type semiconductor layer is less than a preset value to form a high-resistance region.

Processes of performing the step S3 first and then performing step S4 are repeated for N times until the concentration of the magnesium ions on the surface of the P-type semiconductor layer 30 is less than the preset value to form the high-resistance region 31 shown in FIG. 5. The preset value is 1E15/cm³. The concentration of magnesium ions inside the P-type semiconductor layer 30 is greater than 1E17/cm³, and the concentration of the magnesium ions on the surface of the P-type semiconductor layer 30 may be reduced to less than 1E15/cm³ after processes of growing the sacrificial layer 50 first and then etching the sacrificial layer 50 are performed for multiple times, i.e., a concentration of magnesium ions located in the high-resistance region 31 is less than 1E15/cm³

As shown in FIG. 5, the P-type semiconductor layer 30 includes a low-resistance region 32 and the high-resistance region 31 that are stacked along a direction from the substrate 10 to the P-type semiconductor layer 30, and a concentration of magnesium ions located in the low-resistance region 32 may be gradually decreased along the direction from the substrate 10 to the P-type semiconductor layer 30 after processes of growing the sacrificial layer 50 first and then etching the sacrificial layer 50 are performed for multiple times, further reducing a gate leakage current of a semiconductor structure subsequently prepared.

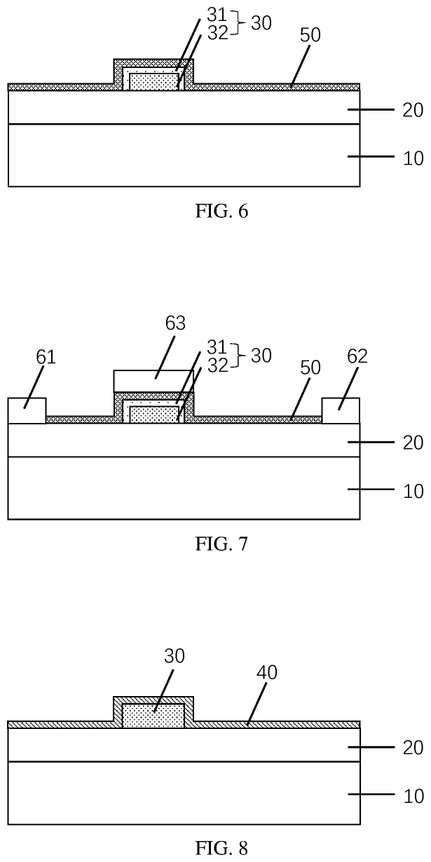

After processes of performing the step S3 first and then performing step S4 are repeated for N times, step S3 is performed again, and as shown in FIG. 6, a last grown sacrificial layer 50 is remained, a material of the sacrificial layer 50 is AlN, and the sacrificial layer 50 at this time may function as a protection layer, avoiding leakage of a device caused by a deterioration of a surface morphology of the P-type semiconductor layer 30 during an annealing process. Before electrodes are prepared, the P-type semiconductor layer 30 is annealed to activate magnesium ions of the P-type semiconductor layer 30, so that a two-dimensional electron gas in the heterojunction structure layer 20 in the gate region is depleted, to implement an enhancement mode device.

After step S5, the method for manufacturing the semiconductor structure further includes: providing a source electrode on the heterojunction structure layer in a source region, providing a drain electrode on the heterojunction structure layer in a drain region, and providing a gate electrode in the gate region.

The source electrode 61 is provided on the heterojunction structure layer 20 in the source region, the drain electrode 62 is provided on the heterojunction structure layer 20 in the drain region, and the gate electrode 63 is provided in the gate region, so as to form a semiconductor structure shown in FIG. 7.

FIG. 8 to FIG. 10 are schematic diagrams of intermediate structures corresponding to a semiconductor structure in a manufacturing process according to another embodiment of the present disclosure. In an embodiment, after step S2 and before step S3, the method for manufacturing the semiconductor structure further includes: conformally providing a protection layer on the P-type semiconductor layer.

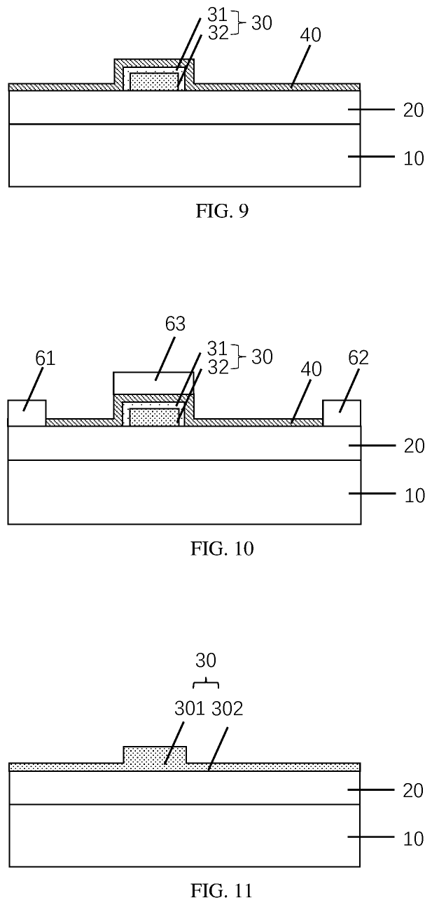

As shown in FIG. 8, the protection layer 40 is conformally provided on the P-type semiconductor layer 30, and a material of the protection layer 40 is different from a material of the P-type semiconductor layer 30. After processes of growing the sacrificial layer 50 on the protection layer 40 first and then etching the sacrificial layer 50 are performed for multiple times, an intermediate structure is formed shown in FIG. 9.

The material of the sacrificial layer 50 is different from the material of the protection layer 40, and an etching selectivity ratio of the sacrificial layer 50 to the protection layer 40 is greater than 1, for example, the material of the sacrificial layer 50 is GaN and the material of the protection layer 40 is AlN, or the material of the sacrificial layer 50 is AlGaN and the material of the protection layer 40 is AlN, or the material of the sacrificial layer 50 is GaN and the material of the protection layer 40 is AlGaN. Optionally, the etching selectivity ratio of the sacrificial layer 50 to the protection layer 40 is less than 1, for example, the material of the sacrificial layer 50 is AlN and the material of the protection layer 40 is AlGaN.

After processes of growing the sacrificial layer 50 first and then etching the sacrificial layer 50 are repeated for multiple times, the electrodes are set, and finally a semiconductor structure is formed shown in FIG. 10.

On the one hand, disposal of the protection layer 40 in this embodiment may protect the P-type semiconductor layer 30, i.e., reduce a damage to the P-type semiconductor layer 30 during the annealing process, so as to improve a quality of the surface morphology of the P-type semiconductor layer 30, improving problems of a leakage voltage and pre-breakdown of a device, and further improving a reliability of the device; on the other hand, the protection layer 40 in this embodiment may function as an etch stop layer, avoiding a damage to the P-type semiconductor layer 30 when the sacrificial layer 50 is subsequently etched.

FIG. 11 to FIG. 13 are schematic diagrams of intermediate structures corresponding to a semiconductor structure in a manufacturing process according to another embodiment of the present disclosure. In one embodiment, as shown in FIG. 11, in step S2, the P-type semiconductor layer 30 in the non-gate region is etched with an etching depth less than a thickness of the P-type semiconductor layer 30, the P-type semiconductor layer 30 in the gate region is a first P-type region 301, and a portion of the P-type semiconductor layer 30 in the non-gate region remained after the P-type semiconductor layer 30 in the non-gate region is etched is a second P-type region 302. A thickness of the second P-type region 302 ranges from 1 nm to 50 nm.

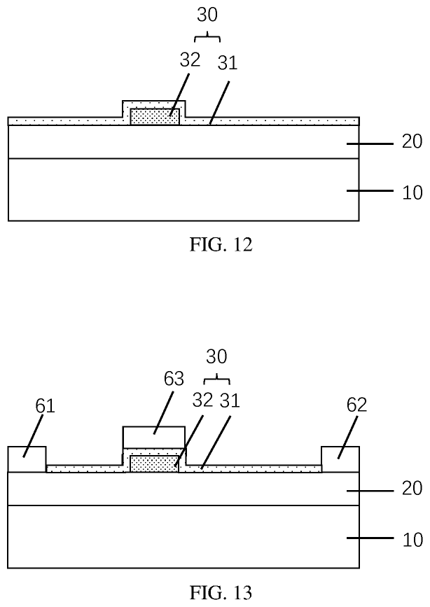

The P-type semiconductor layer 30 in the non-gate region is not completely etched to form the second P-type region 302, so that a quality of a surface of the heterojunction structure layer 20 is not damaged, and the second P-type region 302 may subsequently form a high-resistance region, which may ensure a channel conduction capability. Processes of growing the sacrificial layer 50 on the P-type semiconductor layer 30 first and then etching the sacrificial layer 50 on the P-type semiconductor layer 30 are repeated for N times, so as to form a semiconductor intermediate structure shown in FIG. 12.

Since the thickness of the second P-type region 302 is relatively small, the second P-type region 302 may completely become the high-resistance region 31, i.e., a thickness of the high-resistance region 31 located in the non-gate region is equal to the thickness of the second P-type region 302. Only a surface of the first P-type region 301 becomes the high-resistance region 31. A thickness of the high-resistance region 31 located in the gate region is greater than or equal to the thickness of the second P-type region 302 and is less than a thickness of the first P-type region 301.

Then, the protection layer 40 and the P-type semiconductor layer 30 which are located in the source region and the drain region are etched to expose the heterojunction structure layer 20, the source electrode 61 is provided in the source region, the drain electrode 62 is provided in the drain region, and the gate electrode 63 is provided in the gate region, so as to form a semiconductor structure shown in FIG. 13.

According to another aspect of the present disclosure, the present disclosure further provides a semiconductor structure, and as shown in FIG. 7, the semiconductor structure is prepared by using the method for manufacturing the semiconductor structure mentioned above, which includes: a substrate 10, a heterojunction structure layer 20, and a P-type semiconductor layer 30 sequentially stacked, a source electrode 61 located on the heterojunction structure layer 20 in a source region, a drain electrode 62 located on the heterojunction structure layer 20 in a drain region, and a gate electrode 63 located in a gate region. The P-type semiconductor layer 30 is at least located in the gate region, and a surface of the P-type semiconductor layer 30 is a high-resistance region 31.

In this embodiment, the P-type semiconductor layer 30 includes a low-resistance region 32 and a high-resistance region 31 that are stacked along a direction from the substrate 10 to the P-type semiconductor layer 30, and a concentration of magnesium ions located in the low-resistance region 32 gradually decreases along the direction from the substrate 10 to the P-type semiconductor layer 30.

In one embodiment, as shown in FIG. 11, the P-type semiconductor layer 30 includes a first P-type region 301 located in the gate region and a second P-type region 302 located in a non-gate region, and a thickness of the first P-type region 301 is greater than a thickness of the second P-type region 302. Electrodes are provided after processes of growing a sacrificial layer 50 first and then etching the sacrificial layer 50 are performed for multiple times, so as to form a semiconductor structure shown in FIG. 13.

The present disclosure provides a semiconductor structure and a method for manufacturing the same. The method includes: sequentially stacking a substrate, a heterojunction structure layer, and a P-type semiconductor layer; remaining the P-type semiconductor layer in a gate region and etching the P-type semiconductor layer in a non-gate region; growing a sacrificial layer on the P-type semiconductor layer, and magnesium ions on a surface of the P-type semiconductor layer diffusing into the sacrificial layer; etching the sacrificial layer; repeating N times processes of growing the sacrificial layer first and then etching the sacrificial layer until a concentration of the magnesium ions on the surface of the P-type semiconductor layer is less than a preset value to form a high-resistance region; and providing a source electrode, a drain electrode, and a gate electrode.

In the present disclosure, a method for repeating multiple times processes of growing the sacrificial layer first and then etching the sacrificial layer is adopted, so that the magnesium ions on the surface of the P-type semiconductor layer can be reduced, forming the high-resistance region on the surface of the P-type semiconductor layer, and further obtaining an enhancement mode HEMT device with low gate leakage current, high breakdown voltage, and stable threshold voltage.

On the one hand, disposal of the protection layer in the present disclosure may protect the P-type semiconductor layer, i.e., reduce a damage to the P-type semiconductor layer during an annealing process, so as to improve a quality of a surface morphology of the P-type semiconductor layer, improving problems of a leakage voltage and pre-breakdown of a device, and further improving a reliability of the device; on the other hand, the protection layer 40 in the present disclosure may function as an etch stop layer, avoiding a damage to the P-type semiconductor layer when the sacrificial layer is subsequently etched.

It should be understood that the terms “including” and variations thereof used in the present disclosure are open-ended inclusion, i.e., “including but not limited to”. The term “one embodiment” means “at least one embodiment”; the term “another embodiment” means “at least one other embodiment”. In this specification, schematic representations of the above terms do not necessarily refer to the same embodiment or example. Furthermore, the particular features, structures, materials, or characteristics may be combined in any suitable manner in any one or more embodiments or examples. In addition, different embodiments or examples described in this specification and features of different embodiments or examples may be combined and integrated by a person skilled in the art without contradicting each other.

The above are only preferred embodiments of the present disclosure and are not intended to limit the present disclosure, and any modification, equivalent replacement, and the like made within the spirit and principle of the present disclosure shall fall within the protection scope of the present disclosure.

What is claimed is:

1. A method for manufacturing a semiconductor structure, comprising:
sequentially stacking a substrate, a heterojunction structure layer, and a P-type semiconductor layer;
remaining the P-type semiconductor layer in a gate region and etching the P-type semiconductor layer in a non-gate region;
growing a sacrificial layer on the P-type semiconductor layer, and magnesium ions on a surface of the P-type semiconductor layer diffusing into the sacrificial layer;
etching the sacrificial layer; and
repeating N times processes of growing the sacrificial layer on the P-type semiconductor layer first and then etching the sacrificial layer until a concentration of the magnesium ions on the surface of the P-type semiconductor layer is less than a preset value to form a high-resistance region.

2. The method for manufacturing the semiconductor structure according to claim 1, further comprising:
providing a source electrode on the heterojunction structure layer in a source region, providing a drain electrode on the heterojunction structure layer in a drain region, and providing a gate electrode in the gate region.

3. The method for manufacturing the semiconductor structure according to claim 1, wherein the etching the sacrificial layer comprises:
etching the sacrificial layer by in-situ etching.

4. The method for manufacturing the semiconductor structure according to claim 1, wherein after the high-resistance region is formed, the method for manufacturing the semiconductor structure further comprises:
growing the sacrificial layer on the P-type semiconductor layer, and a material of the sacrificial layer is AlN.

5. The method for manufacturing the semiconductor structure according to claim 1, wherein the sacrificial layer is a non-intentionally doped layer.

6. The method for manufacturing the semiconductor structure according to claim 1, wherein after the remaining the P-type semiconductor layer in a gate region and etching the P-type semiconductor layer in a non-gate region, and before the growing a sacrificial layer on the P-type semiconductor layer, the method for manufacturing the semiconductor structure further comprises:
conformally providing a protection layer on the P-type semiconductor layer.

7. The method for manufacturing the semiconductor structure according to claim 6, wherein a material of the sacrificial layer is different from a material of the protection layer.

8. The method for manufacturing the semiconductor structure according to claim 7, wherein an etching selectivity ratio of the sacrificial layer to the protection layer is greater than 1, the material of the sacrificial layer comprises any one of: GaN and AlGaN, and the material of the protection layer comprises any one of: AlN and AlGaN.

9. The method for manufacturing a semiconductor structure according to claim 7, wherein an etching selectivity ratio of the sacrificial layer to the protection layer is less than 1, the material of the sacrificial layer is AlN, and the material of the protection layer is AlGaN.

10. The method for manufacturing the semiconductor structure according to claim 7, wherein the material of the protection layer is different from a material of the P-type semiconductor layer.

11. The method for manufacturing the semiconductor structure according to claim 1, wherein the etching the P-type semiconductor layer in a non-gate region comprises:
etching the P-type semiconductor layer in the non-gate region with an etching depth less than a thickness of the P-type semiconductor layer, the P-type semiconductor layer in the gate region is a first P-type region, and a portion of the p-type semiconductor layer in the non-gate region remained after the P-type semiconductor layer in the non-gate region is etched is a second P-type region.

12. The method for manufacturing the semiconductor structure according to claim 11, wherein along a direction from the substrate to the P-type semiconductor layer, a thickness of the second P-type region ranges from 1 nm to 50 nm.

13. The method for manufacturing the semiconductor structure according to claim 11, wherein along a direction from the substrate to the P-type semiconductor layer, a thickness of the high-resistance region comprises at least one of:
a thickness of the high-resistance region located in the non-gate region being equal to a thickness of the second P-type region, or
a thickness of the high-resistance region located in the gate region being greater than or equal to a thickness of the second P-type region and less than a thickness of the first P-type region.

14. The method for manufacturing the semiconductor structure according to claim 1, wherein a concentration of magnesium ions inside the P-type semiconductor layer is greater than 1E17/cm³.

15. The method for manufacturing the semiconductor structure according to claim 1, wherein a concentration of magnesium ions located in the high-resistance region is less than 1E15/cm³.

16. The method for manufacturing the semiconductor structure according to claim 1, wherein the P-type semiconductor layer comprises a low-resistance region and the high-resistance region that are stacked along a direction from the substrate to the P-type semiconductor layer, and a concentration of magnesium ions located in the low-resistance region gradually decreases along the direction from the substrate to the P-type semiconductor layer.

17. The method for manufacturing the semiconductor structure according to claim 1, further comprising:
annealing the P-type semiconductor layer to activate magnesium ions of the P-type semiconductor layer.

18. A semiconductor structure, comprising:
a substrate, a heterojunction structure layer, and a P-type semiconductor layer sequentially stacked, the P-type semiconductor layer being at least located in a gate region, and a concentration of magnesium ions on a surface of the P-type semiconductor layer being less than a preset value to form a high-resistance region.

19. The semiconductor structure according to claim 18, wherein the P-type semiconductor layer comprises a first P-type region located in the gate region and a second P-type region located in a non-gate region, and a thickness of the first P-type region is greater than a thickness of the second P-type region along a direction from the substrate to the P-type semiconductor layer.

20. The semiconductor structure according to claim 18, wherein the P-type semiconductor layer comprises a low-resistance region and the high-resistance region that are stacked along a direction from the substrate to the P-type semiconductor layer, and a concentration of magnesium ions located in the low-resistance region gradually decreases along the direction from the substrate to the P-type semiconductor layer.
